(19) United States
(12) Patent Application Publication
(10) Pub. No.: US 2006/0019029 A1
(43) Pub. Date: Jan. 26, 2006

(54) Atomic layer deposition methods and apparatus

(76) Inventors: Kevin T. Hamer, Meridian, ID (US); Philip H. Campbell, Meridian, ID (US); Danny Dynka, Meridian, ID (US); Matthew T. Meyers, Boise, ID (US)

Correspondence Address: WELLS ST. JOHN P.S., 601 W. FIRST AVENUE, SUITE 1300, SPOKANE, WA, 99201, US

(21) Appl. No.: 10/895,482

(22) Filed: Jul. 20, 2004

(51) Int. Cl. C23C 16/00

(52) U.S. Cl. 427/248.1; 118/715

(57) ABSTRACT

The invention includes atomic layer deposition methods and apparatus. In one implementation, an atomic layer deposition apparatus includes a processing chamber, the chamber having an inlet and an outlet; a vacuum source in fluid communication with the outlet; a final valve moveable between an open position and a closed position and having an outlet in fluid communication with the inlet of the chamber and having an inlet; a dump line having an inlet in fluid communication with the inlet of the final valve, the dump line further having an outlet; a safety valve having an outlet in fluid communication with the inlet of the dump line and the inlet of the final valve, the safety valve having an inlet configured to be placed in fluid communication with a fluid source; and an automatic pressure controller in the dump line, between the inlet of the dump line and the outlet of the dump line, and configured to maintain pressure in the dump line at a predetermined pressure at least during a time when the final valve is in the closed position. Other methods and apparatus are provided.

### TECHNICAL FIELD

This invention relates to atomic layer deposition methods and apparatus.

### BACKGROUND OF THE INVENTION

Integrated circuits are typically formed on a semiconductor substrate such as a silicon wafer or other semiconductive material. In general, layers of various materials, which are one of semiconductive, conducting or insulating, are used to form the integrated circuits. By way of example, the various materials are doped, ion implanted, deposited, etched, grown, etc., using various processes. A continuing goal in semiconductor processing is to reduce the size of individual electronic components, thereby enabling smaller and denser integrated circuitry.

As semiconductor devices continue to shrink geometrically, such has had a tendency to result in greater shrinkage in the horizontal dimension than in the vertical dimension. In some instances, the vertical dimension increases. Regardless, the result is increased aspect ratios (height to width) of the devices, making it increasingly important to develop processes that enable materials to conformally deposit over the surfaces of high aspect ratio features.

One process is atomic layer deposition (ALD). With typical ALD, successive mono-atomic layers (monolayers) are deposited or adsorbed to a substrate and/or reacted with the outer layer on the substrate, typically by successive feeding of different precursors to the substrate surface. This occurs within a deposition chamber typically maintained at subatmospheric pressure. ALD was previously known as Atomic Layer Epitaxy, abbreviated ALE.

FIG. 1 shows a prior art ALD system 10. The system 10 includes a processing chamber 12 having an inlet 14 and an outlet 16. The system 10 further includes a vacuum source or pump 18 in fluid communication with the outlet 16 of the chamber 12, to draw exhaust fluid from the chamber 12. The system 10 further includes a final valve 20 having an outlet 22 in fluid communication with the inlet 14 of the chamber 12. The final valve 20 further has an inlet 24. The system 10 further includes a dump line 26 having an inlet 28 in fluid communication with the inlet 24 of the final valve 20. The dump line 26 further has an outlet 30. A dump valve 31 is provided in the dump line 26. The system 10 further includes a vacuum source or pump 19 in fluid communication with the outlet 30 of the dump line 26 to draw fluid from the dump line 26.

A safety valve 32 has an outlet 34 in fluid communication with the inlet 28 of the dump line 26 and the inlet 24 of the final valve 20. The safety valve 32 has an inlet 36 configured to be placed in fluid communication with a fluid source 38 (such as a liquid or gas precursor, purge fluid, or reactant). Although only one precursor or purge fluid source 38 is illustrated, in actual practice there may be one or more precursor fluid sources, one or more reactant sources, and one or more purge fluid sources coupled to the chamber 12, each fluid source 38 having a safety valve, dump valve, final valve, and associated lines.

The purpose of the dump line 26 is to make sure that the lines are full prior to pulsing the final valve 20. In operation, the dump valve 31 is opened when the safety valve 32 is opened, to get fluid flowing, then is turned off before the final valve 20 is operated.

In ALD, precursors are pulsed or otherwise intermittently injected into the reactor chamber 12 for absorption into a substrate or a reaction with other materials therein. Current ALD apparatus use a constant gas flow and inject a precursor or reactant into a chamber for delivery to a wafer surface. This is accomplished by pulsing the final valve 20 for a predetermined time, typically 0.2 to 2 seconds. Typical ALD recipes run as follows: 1) pulse a precursor; 2) purge; 3) pulse a reactant; 4) purge; then repeat these steps for a known number of cycles to generate a film thickness.

Feeding of precursors in ALD systems causes the line pressure to build in advance of the final valve 20 because flow in a gas line is at a constant flow rate. The precursor fluid lines are at constant flow rates to minimize “turn on effects” caused by slow response time of flow controllers. This can cause a significant pressure increase in gas line 40 from, for example, 10 Torr to well over 100 Torr. This correspondingly results in undesired spikes in pressure of the chamber 12 when the final valve 20 is pulsed, as well as a precursor feed to the chamber 12 that is less controlled than desired. Line pressure increases until the final valve 20 is opened to the chamber 12 and thereafter drops drastically, while pressure within the chamber 12 spikes significantly upward. As the final valve 20 is closed, line pressure again builds, and as chamber pressure as well significantly drops, perhaps even before the line valve closes. The bursting effect contributes to a variable deposition rate which, in turn, promotes film uniformity and particle problems. This also severely limits the length of the pulses, due to inability to maintain the requested flow, and is an impediment to process development.

While the invention was motivated in addressing the above issues, it is in no way so limited. The invention is only limited by the accompanying claims as literally worded, without interpretative or other limiting reference to the specification, and in accordance with the doctrine of equivalents.

### SUMMARY

The invention includes atomic layer deposition (ALD) methods and apparatus. In one implementation, an ALD apparatus includes a processing chamber, the chamber having an inlet and an outlet; a vacuum source in fluid communication with the outlet; a final valve moveable between an open position and a closed position and having an outlet in fluid communication with the inlet of the chamber and having an inlet; a dump line having an inlet in fluid communication with the inlet of the final valve, the dump line further having an outlet; a safety valve having an outlet in fluid communication with the inlet of the dump line and the inlet of the final valve, the safety valve having an inlet configured to be placed in fluid communication with a fluid source; and an automatic pressure controller in the dump line, between the inlet of the dump valve and the outlet of the dump valve, and configured to maintain pressure in the dump line at a predetermined pressure at least during a time when the final valve is in the closed position.

Other aspects and implementations are contemplated.

### BRIEF DESCRIPTION OF THE DRAWINGS

Preferred embodiments of the invention are described below with reference to the following accompanying drawings.

FIG. 1 is a schematic view of a prior art atomic layer deposition apparatus.

FIG. 2 is a schematic view of an atomic layer deposition apparatus in accordance with certain embodiments.

FIG. 3 is a schematic view of an atomic layer deposition apparatus in accordance with alternative embodiments.

FIG. 4 is a schematic view of an atomic layer deposition apparatus in accordance with other alternative embodiments.

FIG. 5 is a schematic view of an atomic layer deposition apparatus in accordance with still other alternative embodiments.

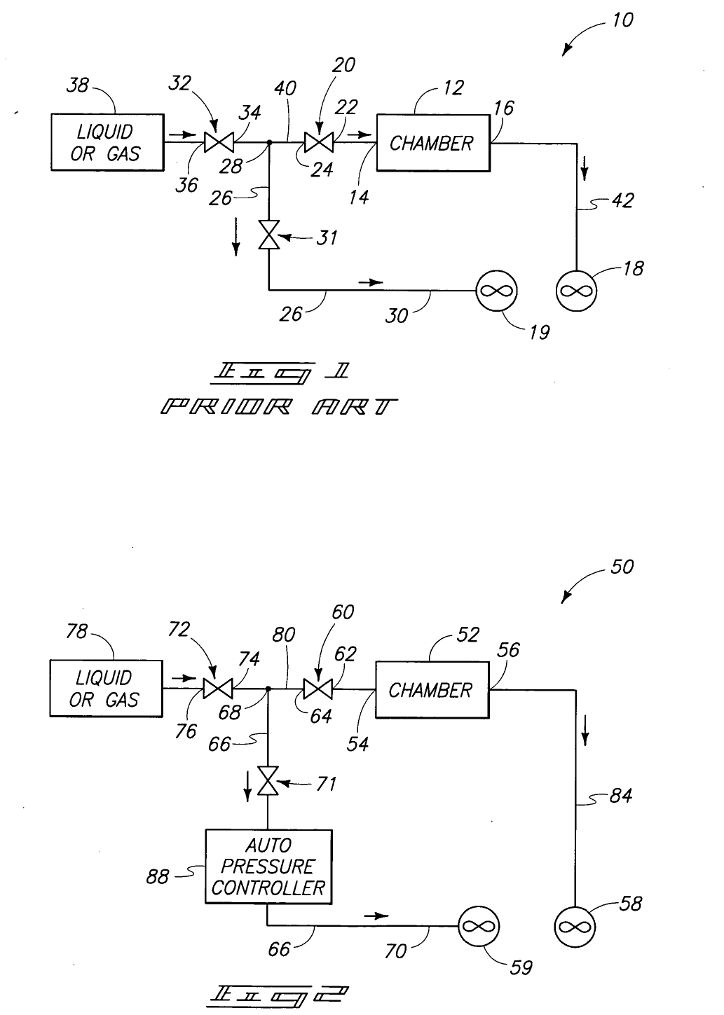

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

The invention comprises atomic layer deposition methods. Atomic layer depositing (ALD) typically involves formation of successive atomic layers on a substrate. Described in summary, ALD includes exposing an initial substrate to a first chemical species to accomplish chemisorbtion of the species onto the substrate. Theoretically, the chemisorbtion forms a monolayer that is uniformly one atom or molecule thick on the entire exposed initial substrate. In other words, a saturated monolayer is preferably formed. Practically, chemisorbtion might not occur on all portions or completely over the desired substrate surfaces. Nevertheless, such an imperfect monolayer is still considered a monolayer in the context of this document. In many applications, merely a substantially saturated monolayer may be suitable. A substantially saturated monolayer is one that will still yield a deposited layer exhibiting the quality and/or properties desired for such layer.

The first species is purged from over the substrate and a second chemical species is provided to chemisorb onto the first monolayer of the first species. The second species is then purged and the steps are repeated with exposure of the second species monolayer to the first species. In some cases, the two monolayers may be of the same species. Also, a third species or more may be successively chemisorbed and purged just as described for the first and second species. Further, one or more of the first, second and third species can be mixed with inert gas to speed up pressure saturation within a reaction chamber.

Purging may involve a variety of techniques including, but not limited to, contacting the substrate and/or monolayer with a carrier gas and/or lowering pressure to below the deposition pressure to reduce the concentration of a species contacting the substrate and/or chemisorbed species. Examples of carrier gases include nitrogen, Ar, He, Ne, Kr, Xe, etc. Purging may instead include contacting the substrate and/or monolayer with any substance that allows chemisorption byproducts to desorb and reduces the concentration of a species preparatory to introducing another species. A suitable amount of purging can be determined experimentally as known to those skilled in the art. Purging time may be successively reduced to a purge time that yields an increase in film growth rate. The increase in film growth rate might be an indication of a change to a non-ALD process regime and may be used to establish a purge time limit.

ALD is often described as a self-limiting process in that a finite number of sites exist on a substrate to which the first species may form chemical bonds. The second species might only bond to the first species and thus may also be self-limiting. Once all of the finite number of sites on a substrate are bonded with a first species, the first species will often not bond to other of the first species already bonded with the substrate. However, process conditions can be varied in ALD to promote such bonding and render ALD not self-limiting. Accordingly, ALD may also encompass a species forming other than one monolayer at a time by stacking of a species, forming a layer more than one atom or molecule thick. Further, local chemical reactions can occur during ALD (for instance, an incoming reactant molecule can displace a molecule from an existing surface rather than forming a monolayer over the surface). To the extent that such chemical reactions occur, they are generally confined within the uppermost monolayer of a surface.

Traditional ALD can occur within frequently-used ranges of temperature and pressure and according to established purging criteria to achieve the desired formation of an overall ALD layer one monolayer at a time. Even so, ALD conditions can vary greatly depending on the particular precursors, layer composition, deposition equipment, and other factors according to criteria known by those skilled in the art. Maintaining the traditional conditions of temperature, pressure, and purging minimizes unwanted reactions that may impact monolayer formation and quality of the resulting overall ALD layer. Accordingly, operating outside the traditional temperature and pressure ranges may risk formation of defective monolayers.

In particular aspects, the present application pertains to atomic layer deposition (ALD) technology. ALD technology typically involves formation of successive atomic layers on a substrate. Such layers may comprise, for example, an epitaxial, polycrystalline, and/or amorphous material. ALD may also be referred to as atomic layer epitaxy, atomic layer processing, etc.

The deposition methods herein are described in the context of formation of materials on one or more semiconductor substrates. In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above. Also in the context of the present document, “metal” or “metal element” refers to the elements of Groups IA, IIA, and IB to VIIIB of the periodic table of the elements along with the portions of Groups IIIA to VIA designated as metals in the periodic table, namely, Al, Ga, In, Tl, Ge, Sn, Pb, Sb, Bi, and Po. The Lanthanides and Actinides are included as part of Group IIIB. “Non-metals” refers to the remaining elements of the periodic table.

Described in summary, ALD includes exposing an initial substrate to a first chemical species to accomplish chemisorption of the species onto the substrate. Theoretically, the chemisorption forms a monolayer that is uniformly one atom or molecule thick on the entire exposed initial substrate, in other words, a saturated monolayer. Practically, as further described below, chemisorption might not occur on all portions of the substrate. Nevertheless, such an imperfect monolayer is still a monolayer in the context of this document. In many applications, merely a substantially saturated monolayer may be suitable. A substantially saturated monolayer is one that will still yield a deposited layer exhibiting the quality and/or properties desired for such layer.

The first species is purged from over the substrate and a second chemical species is provided to chemisorb onto the first monolayer of the first species. The second species is then purged and the steps are repeated with exposure of the second species monolayer to the first species. In some cases, the two monolayers may be of the same species. Also, a third species or more may be successively chemisorbed and purged just as described for the first and second species. It is noted that one or more of the first, second and third species can be mixed with inert gas to speed up pressure saturation within a reaction chamber.

Purging may involve a variety of techniques including, but not limited to, contacting the substrate and/or monolayer with a carrier gas and/or lowering pressure to below the deposition pressure to reduce the concentration of a species contacting the substrate and/or chemisorbed species. Examples of carrier gases include N₂, Ar, He, Ne, Kr, Xe, etc. Purging may instead include contacting the substrate and/or monolayer with any substance that allows chemisorption byproducts to desorb and reduces the concentration of a species preparatory to introducing another species. A suitable amount of purging can be determined experimentally as known to those skilled in the art. Purging time may be successively reduced to a purge time that yields an increase in film growth rate. The increase in film growth rate might be an indication of a change to a non-ALD process regime and may be used to establish a purge time limit.

ALD is often described as a self-limiting process, in that a finite number of sites exist on a substrate to which the first species may form chemical bonds. The second species might only bond to the first species and thus may also be self-limiting. After all of the finite number of sites on a substrate are bonded with a first species, the first species will often not bond to other of the first species already bonded with the substrate. However, process conditions can be varied in ALD to promote such bonding and render ALD not self-limiting. Accordingly, ALD may also encompass a species forming other than one monolayer at a time by stacking of a species, forming a layer more than one atom or molecule thick. The various aspects of the present invention described herein are applicable to any circumstance where ALD may be desired. It is further noted that local chemical reactions can occur during ALD (for instance, an incoming reactant molecule can displace a molecule from an existing surface rather than forming a monolayer over the surface). To the extent that such chemical reactions occur, they are generally confined within the uppermost monolayer of a surface.

Traditional ALD can occur within frequently-used ranges of temperature and pressure and according to established purging criteria to achieve the desired formation of an overall ALD layer one monolayer at a time. Even so, ALD conditions can vary greatly depending on the particular precursors, layer composition, deposition equipment, and other factors according to criteria known by those skilled in the art. Maintaining the traditional conditions of temperature, pressure, and purging minimizes unwanted reactions that may impact monolayer formation and quality of the resulting overall ALD layer. Accordingly, operating outside the traditional temperature and pressure ranges may risk formation of defective monolayers.

The general technology of chemical vapor deposition (CVD) includes a variety of more specific processes, including, but not limited to, plasma enhanced CVD and others. CVD is commonly used to form non-selectively a complete, deposited material on a substrate. One characteristic of CVD is the simultaneous presence of multiple species in the deposition chamber that react to form the deposited material. Such condition is contrasted with the purging criteria for traditional ALD wherein a substrate is contacted with a single deposition species that chemisorbs to a substrate or previously deposited species. An ALD process regime may provide a simultaneously contacted plurality of species of a type or under conditions such that ALD chemisorption, rather than CVD reaction occurs. Instead of reacting together, the species may chemisorb to a substrate or previously deposited species, providing a surface onto which subsequent species may next chemisorb to form a complete layer of desired material.

Under most CVD conditions, deposition occurs largely independent of the composition or surface properties of an underlying substrate. By contrast, chemisorption rate in ALD might be influenced by the composition, crystalline structure, and other properties of a substrate or chemisorbed species. Other process conditions, for example, pressure and temperature, may also influence chemisorption rate. Accordingly, observation indicates that chemisorption might not occur appreciably on portions of a substrate though it occurs at a suitable rate on other portions of the same substrate. Such a condition may introduce intolerable defects into a deposited material.

Various ALD and other methods and apparatus are disclosed, for example, in the following U.S. Patents, all of which are incorporated herein by reference: U.S. Pat. No. 6,723,595 to Park; U.S. Pat. No. 6,699,524 to Kesälä; U.S. Pat. No. 6,620,670 to Song et al.; U.S. Pat. No. 6,579,823; to Moody et al.; U.S. Pat. No. 6,630,201 to Chiang et al.; U.S. Pat. No. 6,045,671 to Wu et al; U.S. Pat. No. 5,499,599 to Lowndes et al; U.S. Pat. No. 5,386,798 to Lowndes et al.; and U.S. Pat. No. 4,058,430 to Suntola et al.

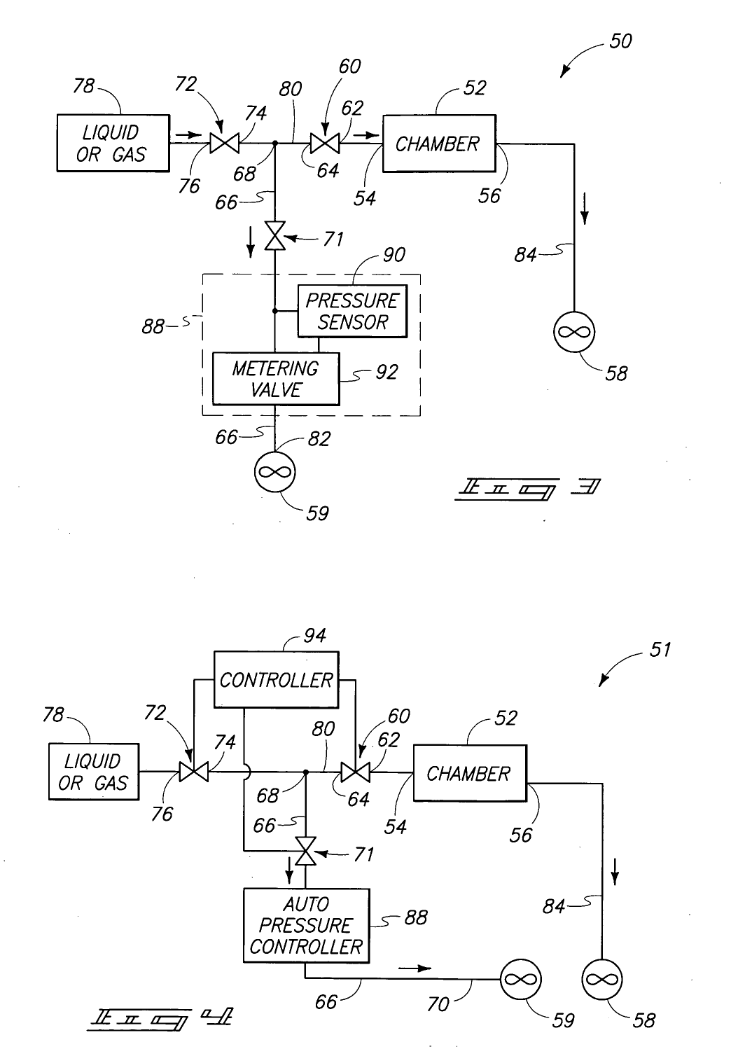

An exemplary preferred embodiment is initially described with reference to FIG. 2. Referring to FIG. 2, there diagrammatically depicted is an ALD system 50. The system 50 includes a processing chamber 52 having an inlet 54 and an outlet 56.

The system 50 further includes a vacuum source or pump 58 in fluid communication with (downstream of) the outlet 56 of the chamber 52 via a line 84. The vacuum source 58 causes gases to be exhausted from the chamber 52 via the line 84.

The system 50 further includes a final valve 60 having an outlet 62 in fluid communication with (upstream of) the inlet 54 of the chamber 52. The final valve 60 further has an inlet 64.

The system 50 further includes a dump (or diversion) line 66 having an inlet 68 in fluid communication with the inlet 64 of the final valve 60. The dump line 66 further has an outlet 70. The system 50 further includes a vacuum source or pump 59 in fluid communication with (downstream of) the outlet 70 of the dump line 66.

The system 50 further includes, in some embodiments, a dump valve 71 in the dump line 66. In the illustrated embodiment, the dump valve 71 is between the inlet 68 and outlet 70 of the dump line 66. In the illustrated embodiment, the dump valve 71 is of a type that is either full open or full closed.

The system 50 further includes a safety valve 72 that has an outlet 74 in fluid communication with (upstream of) the inlet 68 of the dump line 66 and the inlet 64 of the final valve 60. The safety valve 72 has an inlet 76 configured to be placed in fluid communication with a fluid source 78 (such as a liquid or gas precursor, reactant, or purge fluid source). Although only one fluid source 78 is illustrated, in actual practice there may be multiple fluid sources 78 coupled to the chamber 52, each source having a safety valve, dump valve, final valve, and associated fluid lines.

The system 50 further includes an automatic pressure controller 88 in the dump line 66, between the inlet 68 of the dump line 66 and the outlet 70 of the dump line 66, and configured to maintain pressure in the dump line 66 at a predetermined pressure at least during a time when the final valve 60 is in the closed position. In the illustrated embodiment, the dump valve 71 is between the inlet 68 of the dump line and the automatic pressure controller 88; however, other embodiments are possible.

FIG. 3 shows an embodiment similar to the embodiment of FIG. 2, like reference numerals indicating like components, except that the automatic pressure controller 88 comprises a pressure sensor 90, arranged to sense pressure in the dump line 66. The automatic pressure controller 88, by way of example only, is depicted as including a metering valve 92, coupled to the pressure sensor 90. The metering valve 92 controls flow rate therethrough and accordingly causes pressure within the dump line 66 to be variable. Accordingly, the automatic pressure controller 88 can operate to sense pressure in the dump line 66, with the metering valve 92 thereof operating to control pressure within the dump line 66 at a desired or predetermined pressure.

In the illustrated embodiment, the dump valve 71 is configured to open in response to the safety valve 72 being opened. In some embodiments, the dump valve 71 is configured to open at all times while the safety valve 72 is open.

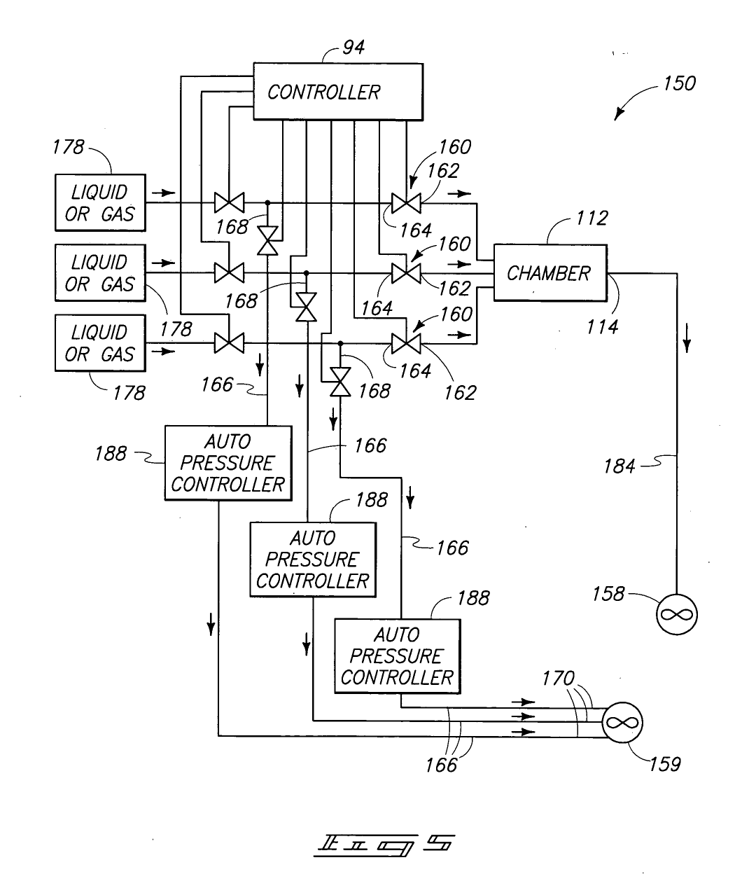

FIG. 4 shows a system 51 similar to the embodiment of FIG. 2 but which further includes a controller 94 (such as a computer, processor, or programmable logic controller) coupled to the safety valve 72, final valve 60, and dump valve 71. In the illustrated embodiment, the controller 94 causes, in operation, the dump valve 71 to open while the safety valve 72 is open. The controller 94, in operation, sends signals at appropriate times to operate, open, or close desired valves to achieve the pulsing of the precursors at desired times and sequences. In some embodiments, the controller 94 is not coupled to the metering valve 92 (FIG. 3). The controller 94 is not necessarily coupled with the automatic pressure controller 88 because the automatic pressure controller 88 can self-operate without the controller 94. In some alternative embodiments (not shown) the outlet 70 of the dump line 66 is in fluid communication with the vacuum source 58 instead of a separate vacuum source 58.

In operation, the automatic pressure controller 88 is utilized in the dump line 66, with the dump valve 71 always being open, or at least opened simultaneously with the opening of the safety valve 72. Accordingly, the dump line 66 sees the same pressure as in the feed line 80 immediately prior to the final valve 60. The pressure sensor 90 (FIG. 3) comprises a transducer that measures line pressure, and is a part of the automatic pressure controller 88.

The system 51 might operate in any of a number of different ways. For example, where it is desirable to precisely control line pressure and chamber pressure to be substantially constant, or at least not as variable as in the prior art, in some embodiments the controller 94 operates to open and close the final valve 60 and the dump valve 71 simultaneously. The final valve 60 is then operated to feed, for example, precursor into the chamber 52 at desired intervals when the final valve 60 and dump valve 71 are open. However, there may be a lag time after the final valve 60 closes for pressure to build back up to a desired value within the line 80 upstream of the final valve 60. By way of example of a different manner of operation of the system 51, in some embodiments the controller 94 might operate to close the dump valve 71 momentarily or for some time at or after opening of the final valve 60, with the dump valve 71 not being opened for some time such that pressure can build up more quickly within the line 80 upstream of the final valve. In this manner, pressure in the line 80 may build up quicker than with the dump valve 71 being open.

In some embodiments, open or closed loop control is utilized (e.g., by the controller 94) relative to the automatic pressure controller 88 such that the flow rate of the metering valve 92 is controlled based upon feedback or based upon how control had occurred during a preceding cycle or cycles to allow pressure in the line 80 to build up more quickly. In these embodiments, the dump valve 71 may be omitted or left open after opening of the final valve 60.

Some embodiments of the invention also contemplate merely including a pressure relief valve within a dump line of any sort of ALD system, which valve operates upstream or downstream of the dump valve, thereby maintaining pressure upstream based on the set value of the pressure relief valve.

In operation, precursors are pulsed or otherwise intermittently injected into the reactor chamber 52 for absorption into a substrate or a reaction with other materials therein. A constant gas flow is provided and a precursor or reactant is injected into the chamber for delivery to a wafer surface. This is accomplished by pulsing the final valve 60 for a predetermined time, typically 0.2 to 2 seconds.

Although only one fluid source 78 is illustrated in FIGS. 2-4, in actual practice there may be one or more precursor fluid sources, one or more reactant fluid sources, and one or more purge fluid sources coupled to the chamber 52. Respective fluid sources have a safety valve, dump valve, final valve, and associated lines. Thus, FIG. 5 illustrates an ALD system 150 having one or more fluid sources 178 and one or more purge fluid sources 178 coupled to a chamber 112. The system 150 includes a vacuum source or pump 158. The chamber 112 further has a fluid exhaust 114 fluidly coupled to the pump 158. The system 150 includes a plurality of final valves 160, each final valve 160 being moveable between an open position and a closed position. Each final valve 160 has an outlet 162 in fluid communication with the chamber 112, and each final valve 160 has an inlet 164. The system 150 includes a plurality of dump lines 166. Each dump line 166 has an inlet 168 in fluid communication with the inlet 164 of one of the final valves 160. Each dump line 166 further has an outlet 170 in fluid communication with a vacuum source, such as pump 159, or, in alternative embodiments, to line 184, or to multiple vacuum sources. The inlets 168 of respective dump lines 166 and final valves 160 are placed in fluid communication with respective process fluid sources (precursor or purge fluid sources) 178. The system 150 further includes an automatic pressure controller 188 in each dump line 166. The automatic pressure controller 188 of each dump line 166 maintains pressure in the dump line 166 at a predetermined pressure at least during a time when the final valve 160 that is in fluid communication with the dump line is in the closed position.

An example of an ALD recipe that could be performed using the system 150 is to: 1) pulse a precursor; 2) purge; 3) pulse a reactant; 4) purge; then repeat these steps for a known number of cycles to generate a film thickness.

An ALD method comprises defining a processing chamber, the chamber having an inlet and an outlet; placing a vacuum source in fluid communication with the outlet; placing an outlet of a final valve in fluid communication with the inlet of the chamber, the final valve being moveable between an open position and a closed position; placing an inlet of a dump line in fluid communication with an inlet of the final valve; placing an outlet of a safety valve in fluid communication with the inlet of the dump line and an inlet of the final valve, placing an inlet of the safety valve in fluid communication with a fluid source; and maintaining pressure in the dump line at a predetermined pressure at least during a time when the final valve is in the closed position.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents. For example and by way of example only, the invention does not preclude and contemplates combination of the claimed atomic layer depositing with other deposition methods before or after the claimed atomic layer depositing in forming porous oxide on the substrate.

The invention claimed is:

1. An atomic layer deposition apparatus comprising:
a processing chamber, the chamber having an inlet and an outlet;
a vacuum source in fluid communication with the outlet;
a final valve moveable between an open position and a closed position and having an outlet in fluid communication with the inlet of the chamber and having an inlet;
a dump line having an inlet in fluid communication with the inlet of the final valve, the dump line further having an outlet;
a safety valve having an outlet in fluid communication with the inlet of the dump line and the inlet of the final valve, the safety valve having an inlet configured to be placed in fluid communication with a fluid source; and
an automatic pressure controller in the dump line, between the inlet of the dump line and the outlet of the dump line, and configured to maintain pressure in the dump line at a predetermined pressure at least during a time when the final valve is in the closed position.

2. An atomic layer deposition apparatus in accordance with claim 1 and comprising a dump valve in the dump line, between the inlet and outlet of the dump line.

3. An atomic layer deposition apparatus in accordance with claim 2 wherein the dump valve is between the inlet of the dump line and the automatic pressure controller.

4. An atomic layer deposition apparatus in accordance with claim 2 wherein the automatic pressure controller comprises a metering valve.

5. An atomic layer deposition apparatus in accordance with claim 1 wherein the automatic pressure controller comprises a pressure sensor, arranged to sense pressure in the dump line, and a metering valve coupled to the pressure sensor.

6. An atomic layer deposition apparatus in accordance with claim 2 wherein the dump valve is of a type that is either full open or full closed.

7. An atomic layer deposition apparatus in accordance with claim 2 wherein the dump valve is configured to open in response to the safety valve being opened.

8. An atomic layer deposition apparatus in accordance with claim 2 wherein the dump valve is configured to open at all times while the safety valve is open.

9. An atomic layer deposition apparatus in accordance with claim 2 and comprising a controller coupled to the safety valve, final valve, and dump valve.

10. An atomic layer deposition apparatus in accordance with claim 2 and comprising a controller coupled to the safety valve, final valve, and dump valve and configured to cause the dump valve to open while the safety valve is open.

11. An atomic layer deposition apparatus in accordance with claim 4 and comprising a controller coupled to the safety valve, final valve, and dump valve but not to the metering valve.

12. An atomic layer deposition apparatus in accordance with claim 4 and further comprising a controller coupled to the safety valve, final valve, and dump valve and configured to cause the dump valve to close in response to the final valve opening.

13. A processing system for forming a layer on a substrate, the system comprising:
a chamber, the chamber having a fluid inlet and a fluid exhaust;
a fluid line in fluid communication with the inlet;
a final valve moveable between an open position and a closed position and having an outlet coupled to the fluid line and having an inlet;
a dump line having an inlet in fluid communication with the inlet of the final valve, the dump line further having an outlet configured to be placed in fluid communication with a pump, the inlet of the dump line and inlet of the final valve both being configured to be placed in fluid communication with a precursor fluid source; and
an automatic pressure controller in the dump line, between the inlet of the dump line and the outlet of the dump line, and configured to maintain pressure in the dump line at a predetermined pressure at least during a time when the final valve is in the closed position.

14. A processing system in accordance with claim 13 and comprising a dump valve in the dump line.

15. A processing system in accordance with claim 14 wherein the dump valve is between the inlet of the dump line and the automatic pressure controller.

16. A processing system in accordance with claim 14 wherein the automatic pressure controller comprises a metering valve.

17. A processing system in accordance with claim 13 wherein the automatic pressure controller comprises a pressure sensor, arranged to sense pressure in the dump line, and a metering valve coupled to the pressure sensor.

18. A processing system in accordance with claim 14 wherein the dump valve is a full open/full closed valve.

19. A processing system in accordance with claim 14 and comprising a safety valve having an outlet in fluid communication with the inlet of the dump line and the inlet of the final valve, the safety valve having an inlet configured to be placed in fluid communication with a precursor fluid source, and a controller configured to cause the dump valve to open in response to the safety valve being opened.

20. A processing system in accordance with claim 14 and comprising a safety valve having an outlet in fluid communication with the inlet of the dump line and the inlet of the final valve, the safety valve having an inlet configured to be placed in fluid communication with a precursor fluid source, and a controller configured to cause the dump valve to open at all times while the safety valve is open.

21. A processing system in accordance with claim 14 and comprising a safety valve having an outlet in fluid communication with the inlet of the dump line and the inlet of the final valve, the safety valve having an inlet configured to be placed in fluid communication with a precursor fluid source, and a programmable logic controller configured to separately control the safety valve, final valve, and dump valve.

22. A processing system in accordance with claim 14 and comprising a safety valve having an outlet in fluid communication with the inlet of the dump line and the inlet of the final valve, the safety valve having an inlet configured to be placed in fluid communication with a precursor fluid source, and a programmable logic controller electrically coupled to the safety valve, final valve, and dump valve and configured to cause the dump valve to open while the safety valve is open.

23. A processing system in accordance with claim 16 and comprising a programmable logic controller electrically coupled to the final valve, and dump valve but not to the metering valve.

24. A processing system in accordance with claim 16 and comprising a safety valve having an outlet in fluid communication with the inlet of the dump line and the inlet of the final valve, the safety valve having an inlet configured to be placed in fluid communication with a precursor fluid source, and a programmable logic controller coupled to the safety valve, final valve, and dump valve, but not to the metering valve, and configured to cause the dump valve to open while the safety valve is open.

25. A processing system in accordance with claim 16 and comprising a pump in fluid communication with the outlet of the dump valve and the exhaust of the chamber.

26. A processing system for forming a layer on a substrate, the system comprising:
a chamber, the chamber having a fluid exhaust;
a plurality of final valves, each final valve being moveable between an open position and a closed position, each final valve having an outlet in fluid communication with the chamber, and each final valve having an inlet;
a plurality of dump lines, each dump line having an inlet in fluid communication with the inlet of one of the final valves, each dump line further having an outlet configured to be placed in fluid communication with a vacuum source, the inlets of respective dump lines and final valves being configured to be placed in fluid communication with respective process fluid sources; and
an automatic pressure controller in each dump line and configured to maintain pressure in the dump line at a predetermined pressure at least during a time when the final valve that is in fluid communication with the dump line is in the closed position.

27. A processing system in accordance with claim 26 and comprising a dump valve in each dump line.

28. A processing system in accordance with claim 27 wherein the respective dump valves are between the inlet of the dump line and the automatic pressure controller.

29. A processing system in accordance with claim 27 wherein the automatic pressure controllers comprise metering valves.

30. A processing system in accordance with claim 26 wherein the automatic pressure controllers comprise pressure sensors, arranged to sense pressure in the respective dump lines, and metering valves coupled to respective pressure sensors.

31. A processing system in accordance with claim 27 wherein the dump valves comprise full open/full closed valves.

32. A processing system in accordance with claim 27 and comprising a plurality of safety valves, each safety valve having an outlet in fluid communication with the inlet of one of the dump lines and the inlet of one of the final valves, the safety valves each having an inlet configured to be placed in fluid communication with a precursor fluid source, and the processing system further including a controller configured to cause respective dump valves to open in response to safety valves being opened.

33. A processing system in accordance with claim 27 and comprising a plurality of safety valves, each safety valve having an outlet in fluid communication with the inlet of one of the dump lines and the inlet of one of the final valves, the safety valves each having an inlet configured to be placed in fluid communication with a precursor fluid source, and the processing system further including a controller configured to cause respective dump valves to open at all times while the safety valve in communication with the dump valve is open.

34. A processing system in accordance with claim 27 and comprising a programmable logic controller electrically coupled to separately control the final valves and dump valves.

35. A processing system in accordance with claim 27 and comprising a plurality of safety valves, each safety valve having an outlet in fluid communication with the inlet of one of the dump lines and the inlet of one of the final valves, the safety valves each having an inlet configured to be placed in fluid communication with a precursor fluid source, and the processing system further including a controller configured to cause respective dump valves to open while the safety valve in communication with the dump valve is open.

36. A processing system in accordance with claim 29 and comprising a plurality of safety valves, each safety valve having an outlet in fluid communication with the inlet of one of the dump lines and the inlet of one of the final valves, the safety valves each having an inlet configured to be placed in fluid communication with a precursor fluid source, the processing system further including a programmable logic controller configured to cause respective dump valves to open while the safety valve in communication with the dump valve is open, the programmable logic controller being electrically coupled to the safety valves, final valves, and dump valves but not to the metering valves.

37. A processing system in accordance with claim 27 and comprising a pump in fluid communication with the outlet of the dump valves and the exhaust of the chamber.

38. An atomic layer deposition method comprising:
defining a processing chamber, the chamber having an inlet and an outlet;
placing a vacuum source in fluid communication with the outlet;
placing an outlet of a final valve in fluid communication with the inlet of the chamber, the final valve being moveable between an open position and a closed position;
placing an inlet of a dump line in fluid communication with an inlet of the final valve;
placing an outlet of a safety valve in fluid communication with the inlet of the dump line and an inlet of the final valve, placing an inlet of the safety valve in fluid communication with a fluid source; and
maintaining pressure in the dump line at a predetermined pressure at least during a time when the final valve is in the closed position.

39. An atomic layer deposition method in accordance with claim 38 and comprising placing a dump valve in the dump line, between the inlet and outlet of the dump line.

40. An atomic layer deposition method in accordance with claim 39 wherein the dump valve is placed between the inlet of the dump line and the automatic pressure controller.

41. An atomic layer deposition method in accordance with claim 39 wherein maintaining pressure comprises employing a metering valve.

42. An atomic layer deposition method in accordance with claim 38 wherein maintaining pressure comprises employing a pressure sensor, arranged to sense pressure in the dump line, and a metering valve coupled to the pressure sensor.

43. An atomic layer deposition method in accordance with claim 39 wherein the dump valve is of a type that is either full open or full closed.

44. An atomic layer deposition method in accordance with claim 39 wherein the dump valve is configured to open in response to the safety valve being opened.

45. An atomic layer deposition method in accordance with claim 39 wherein the dump valve is configured to open at all times while the safety valve is open.

46. An atomic layer deposition method in accordance with claim 39 and comprising coupling a controller to the safety valve, final valve, and dump valve.

47. An atomic layer deposition method in accordance with claim 39 and comprising coupling a controller to the safety valve, final valve, and dump valve and configuring the controller to cause the dump valve to open while the safety valve is open.

48. An atomic layer deposition method in accordance with claim 41 and comprising coupling a controller to the safety valve, final valve, and dump valve but not to the metering valve.

49. An atomic layer deposition method in accordance with claim 41 and comprising reducing fluid flow in the dump line, at least for some amount of time, in response to the final valve opening.

50. A method for forming a layer on a substrate, the method comprising:
defining a chamber, the chamber having a fluid inlet and a fluid exhaust;
placing a fluid line in fluid communication with the inlet;
placing an outlet of a final valve in fluid communication with the fluid line, the final valve being moveable between an open position and a closed position, the final valve having an inlet;
placing an inlet of a dump line in fluid communication with the inlet of the final valve, and placing an outlet of the dump line in fluid communication with a pump, the inlet of the dump line and inlet of the final valve both being configured to be placed in fluid communication with a precursor fluid source; and
placing an automatic pressure controller in the dump line, between the inlet of the dump line and the outlet of the dump line, and configuring the automatic pressure controller to maintain pressure in the dump line at a predetermined pressure at least during a time when the final valve is in the closed position.

51. A method in accordance with claim 50 and comprising placing a dump valve in the dump line.

52. A method in accordance with claim 51 wherein the dump valve is placed between the inlet of the dump line and the automatic pressure controller.

53. A method in accordance with claim 51 wherein the automatic pressure controller comprises a metering valve.

54. A method in accordance with claim 50 wherein the automatic pressure controller comprises a pressure sensor, arranged to sense pressure in the dump line, and a metering valve coupled to the pressure sensor.

55. A method in accordance with claim 51 wherein the dump valve is a full open/full closed valve.

56. A method in accordance with claim 51 and comprising placing an outlet of a safety valve in fluid communication with the inlet of the dump line and the inlet of the final valve, the safety valve having an inlet configured to be placed in fluid communication with a precursor fluid source, the method further comprising causing the dump valve to open in response to the safety valve being opened.

57. A method in accordance with claim 51 and comprising placing an outlet of a safety valve in fluid communication with the inlet of the dump line and the inlet of the final valve, the safety valve having an inlet configured to be placed in fluid communication with a precursor fluid source, the method further comprising causing the dump valve to open at all times while the safety valve is open.

58. A method in accordance with claim 51 and comprising placing an outlet of a safety valve in fluid communication with the inlet of the dump line and the inlet of the final valve, the safety valve having an inlet configured to be placed in fluid communication with a precursor fluid source, the method further comprising coupling a programmable logic controller to separately control the safety valve, final valve, and dump valve.

59. A method in accordance with claim 51 and comprising placing an outlet of a safety valve in fluid communication with the inlet of the dump line and the inlet of the final valve, the safety valve having an inlet configured to be placed in fluid communication with a precursor fluid source, the method further comprising electrically coupling a programmable logic controller to the safety valve, final valve, and dump valve and configuring the programmable logic controller to cause the dump valve to open while the safety valve is open.

60. A method in accordance with claim 53 and comprising electrically coupling a programmable logic controller to the final valve and dump valve but not to the metering valve.

61. A method in accordance with claim 53 and comprising placing an outlet of a safety valve in fluid communication with the inlet of the dump line and the inlet of the final valve, the safety valve having an inlet configured to be placed in fluid communication with a precursor fluid source, and a programmable logic controller coupled to the safety valve, final valve, and dump valve, but not to the metering valve, the programmable logic controller being configured to cause the dump valve to open while the safety valve is open.

62. A method in accordance with claim 53 and comprising a pump in fluid communication with the outlet of the dump valve and the exhaust of the chamber.

63. A method for forming a layer on a substrate, the method comprising:
defining a chamber having a fluid exhaust;
providing a plurality of final valves, each final valve being moveable between an open position and a closed position, each final valve having an outlet in fluid communication with the chamber, and each final valve having an inlet;
providing a plurality of dump lines, each dump line having an inlet in fluid communication with the inlet of one of the final valves, each dump line further having an outlet configured to be placed in fluid communication with a vacuum source, the inlets of respective dump lines and final valves being configured to be placed in fluid communication with respective precursor fluid sources; and
maintaining pressure in each dump line at a predetermined pressure at least during a time when the final valve that is in fluid communication with the dump line is in the closed position.

64. A method in accordance with claim 63 and comprising a dump valve in each dump line.

65. A method in accordance with claim 64 wherein the dump valves comprise full open/full closed valves.

66. A method in accordance with claim 64 and comprising providing a plurality of safety valves, each safety valve having an outlet in fluid communication with the inlet of one of the dump lines and the inlet of one of the final valves, the safety valves each having an inlet configured to be placed in fluid communication with a precursor fluid source, and the method further comprising configuring respective dump valves to open, in operation, in response to safety valves being opened.

67. A method in accordance with claim 64 and comprising providing a plurality of safety valves, each safety valve having an outlet in fluid communication with the inlet of one of the dump lines and the inlet of one of the final valves, the safety valves each having an inlet configured to be placed in fluid communication with a precursor fluid source, and the method further comprising causing respective dump valves to open at all times while the safety valve in communication with the dump valve is open.

68. A method in accordance with claim 64 and comprising a programmable logic controller electrically coupled to separately control the final valves and dump valves.

69. A method in accordance with claim 64 and comprising providing a plurality of safety valves, each safety valve having an outlet in fluid communication with the inlet of one of the dump lines and the inlet of one of the final valves, the safety valves each having an inlet configured to be placed in fluid communication with a precursor fluid source, and the method further comprising providing a controller configured to cause respective dump valves to open while the safety valve in communication with the dump valve is open.

70. A method in accordance with claim 64 and comprising providing a plurality of safety valves, each safety valve having an outlet in fluid communication with the inlet of one of the dump lines and the inlet of one of the final valves, the safety valves each having an inlet configured to be placed in fluid communication with a precursor fluid source, the method further comprising providing a programmable logic controller configured to cause respective dump valves to open while the safety valve in communication with the dump valve is open, the programmable logic controller being electrically coupled to the safety valves, final valves, and dump valves but not to the metering valves.

71. A method in accordance with claim 64 and comprising placing a pump in fluid communication with the outlet of the dump valves and the exhaust of the chamber.

72. An atomic layer deposition apparatus comprising:
a processing chamber, the chamber having an inlet and an outlet;
a vacuum source in fluid communication with the outlet;
a final valve moveable between an open position and a closed position and having an outlet in fluid communication with the inlet of the chamber and having an inlet;
a dump line having an inlet in fluid communication with the inlet of the final valve, the dump line further having an outlet;
a safety valve having an outlet in fluid communication with the inlet of the dump line and the inlet of the final valve, the safety valve having an inlet configured to be placed in fluid communication with a precursor fluid source; and
an automatic pressure controller in the dump line, between the inlet of the dump line and the outlet of the dump line, and configured to maintain pressure in the dump line at a predetermined pressure at least during a time when the final valve is in the closed position.
